(19) United States
(12) Patent Application Publication
(10) Pub. No.: US 2002/0003275 A1
(43) Pub. Date: Jan. 10, 2002

(54) Shallow trench isolation type semiconductor device and method of the same

(76) Inventors: Keum-Joo Lee, Namdong-ku (KR); Tai-Su Park, Suwon (KR); Young-min Kwon, Suwon (KR); Bong-Ho Moon, Suwon (KR); In-Seak Hwang, Suwon (KR); Chang-Lyoung Song, Yongin-shi (KR)

Correspondence Address: The Law Offices of Eugene M Lee, PLLC, Suite 1200, 2111 Wilson Boulevard, Arlington, VA, 22201, US

(21) Appl. No.: 09/899,224

(22) Filed: Jul. 6, 2001

(30) Foreign Application Priority Data
Jul. 10, 2000 (KR) 2000-39319

(51) Int. Cl. H01L 29/00

(52) U.S. Cl. 257/510

(57) ABSTRACT

A shallow trench type (STI) type semiconductor device employs an etch-stop layer pull-pack approach and a liner as an oxygen barrier, enhancing stability of gate insulation and reliability of transistor operation, wherein a trench sidewall thermal oxide layer with a thickness of 20 Å-140 Å is formed between silicon substrate and the liner, controlling the sidewall liner tension that acts on the substrate. This makes it possible to control the thickness of a gate insulating layer adjacent to a trench to a value equal to or greater than a value in the middle of an active region. Further, a corner adjacent to the trench is rounded to increase the voltage handling capability of device.

### BACKGROUND OF THE INVENTION

1. Field of the Invention

The present invention generally relates to a shallow trench isolation type semiconductor device and a method of the same. More specifically, the present invention is directed to a shallow trench isolation type semiconductor device with a pull-back manner and a method of forming the same.

2. Description of the Related Art

As the integration level of semiconductor devices increases, the use of conventional local oxidation of silicon (LOCOS) process for device isolation has declined. Meanwhile, a shallow trench isolation (STI) process has become widely used.

In the STI technique, a semiconductor substrate area is selectively etched to form a trench for isolating each device area. The trench is then filled with an insulating layer. An inner wall is oxidized, however, because oxygen is diffused from an oxide layer into the substrate during the step of filling the trench with the oxide layer or a subsequent thermal step. The oxidized inner wall increases in volume, doing damage such as introducing dislocations into the crystal structure of the substrate.

A method of preventing crystal structure damage with the use of a silicon nitride liner is disclosed in U.S. Pat. No. 5,747,866, entitled: “Application Of Thin Crystalline Si₃N₄ Liners In Shallow Trench Isolation (STI) Structures,” which issued to Herbert Ho et al. on May 5, 1998. If a silicon nitride layer is formed on an inner wall of a trench before filling the trench with silicon oxide, crystallinity of the semiconductor substrate is not influenced by an oxidized inner wall because the silicon nitride layer serves as a diffusion barrier layer of oxygen. Nevertheless, the silicon nitride liner causes several disadvantages.

FIG. 1 through FIG. 4 illustrate a disadvantage resulting from a silicon nitride liner that is formed on a trench inner wall.

Referring now to FIG. 1, an etch-stop layer 13 made of silicon nitride is stacked on a pad oxide layer 11 that was formed on a substrate 10. The etch-stop layer 13 on top of an intended trench area is removed by means of a patterning procedure consisting of conventional photolithographic exposure and etching. Using the remaining etch-stop layer 13 as an etching mask, the substrate 10 is etched to form a trench 15.

Referring to FIG. 2, a sidewall oxide layer 17 is formed on a trench sidewall using a thermal oxidation technique, which has a thickness of 200 Å-300 Å. The sidewall oxide layer 17 serves to cure the silicon substrate 10, of the trench sidewall, whose crystal structure is damaged by the etching step during the formation of trench 15. A silicon nitride layer is stacked on an entire surface of the substrate 10, forming a liner 19 on the trench sidewall.

Referring to FIG. 3, a CVD silicon oxide layer 21 is stacked on the substrate 10 on which the liner 19 is formed, filling the trench. A step of planarization is carried out to remove the CVD silicon oxide layer 21 that is stacked on an etch-stop layer 13 of an active region.

Referring to FIG. 4, an etch-stop layer covering an active region is removed by means of wet etch. Also, the trench inner wall liner coupled to the etch-stop layer is partially removed. During an over-etch process for completely removing the etch-stop layer, the over-etch is carried out deeply along a layer of the liner. As a result of the over-etch, a shrunk liner 19′ remains between a device isolation layer and an active region. A hollow space is created in a spot of a removed liner, which is called a dent phenomenon. If a CVD silicon oxide layer 21 and a sidewall oxide layer are etched, the hollow space is enlarged further due to a cleaning solution.

If the dent phenomenon occurs, polysilicon, which later fills the hollow space, would cause a gate-bridge phenomenon. The polysilicon makes a parasite transistor, resulting in a hump phenomenon and increased peripheral leakage current.

The STI technique, employing an etch stop layer pull-back approach is used to prevent the dent phenomenon. In accordance with Korean Patent Application No. 98-21037, a trench is formed and an etch-stop layer covering an active region is partially removed by an isotropic etch as shown in of FIG. 5. A lateral end of an etch-stop layer is removed to form a shrunk pattern 13′ and expose an active region around the trench 15 (see FIG. 5). The trench sidewall is oxidized, and a silicon nitride liner is formed. The oxide layer 17, formed on the trench sidewall, has a thickness of 150 Å-300 Å. The liner 19 is formed to cover most of a peripheral upper corner of the active region (see FIG. 6).

With reference to FIGS. 6 and 7, the trench is filled with a CVD silicon oxide layer 21, and the resulting structure is planarized. When the shrunk pattern 13′ is wet etched and the liner 19 is partially removed, the liner 19 is removed over an active region and a liner 19′ remains on the trench sidewall. This makes it possible to prevent the dent phenomenon, which creates a concave space on an upper portion of the trench sidewall.

Since the dent phenomenon does not occur in a pull-back approach, the liner 19′ and the trench sidewall oxide layer 17 are located on a corner sidewall atop a periphery of an active region of the substrate. After removing the etch-stop layer 13′ and the pad oxide layer 11 and while forming a gate insulating layer, oxygen is not easily supplied to the corner region. Therefore, a very thin oxide layer is formed at the corner region in comparison with the gate insulating layer on the other active region locations, as shown in FIG. 8. This causes the following problems: a value of a breakdown charge Q_{bd} is lowered to weaken reliability of insulation, and a leakage current is generated. In FIG. 8, a polysilicon layer is formed over the gate insulating layer to act as a gate electrode.

### SUMMARY OF THE INVENTION

A feature of an embodiment of the present invention is to provide a semiconductor device capable of suppressing a dent phenomenon and solving problems caused by a thin gate insulating layer formed at a corner around an active region, and a method of forming the same.

According to one aspect of an embodiment of the present invention, a shallow trench isolation (STI) type semiconductor device employs a liner as an oxygen barrier. The STI-type semiconductor device includes a trench sidewall thermal oxide layer formed to a thickness of 20 Å-140 Å between the liner and a silicon substrate. The top of the liner is located at a position where a level difference from the top of the liner to an upper surface of the substrate is 150 Å or less. This generally means that the pull-back manner is employed. Additionally, the thickness of the trench sidewall oxide layer is 50 Å-100 Å. The thickness of a gate insulating layer adjacent to a trench is identical to or greater than the thickness of a gate insulating layer in the middle of an active region.

According to another aspect of an embodiment of the present invention, there is provided a method of forming a shallow trench isolation (STI) type semiconductor device. A substrate, where a pattern of an etch-stop layer covers an active region, is etched to form a trench. A thermal oxide layer is formed on a sidewall of the trench. The etch-stop layer pattern is isotropically etched and a lateral end of the pattern is removed to a predetermined width, forming a shrunk pattern. A liner used as an oxygen barrier is stacked on the thermal oxide layer on the substrate where the shrunk pattern is formed. A CVD silicon oxide layer is stacked on the substrate where the liner is formed, filling the trench. The CVD silicon oxide layer is removed and planarized over the etch-stop layer. The shrunk pattern is removed, and a gate oxide layer is formed at the active region.

Thickness of the trench thermal oxide layer is controlled to be 20 Å-140 Å. More preferably, a thickness of the thermal oxide layer is controlled to be 50 Å-100 Å. The etch-stop layer is made of silicon nitride. Controlling the thermal oxide layer thickness within a range of 20 Å-140 Å is done by forming the thermal oxide layer of thickness greater than this thickness range, and etching the thermal oxide layer to reach the required thickness range by means of an F-contained etchant. In forming the predetermined width, the shrunk pattern width is chosen in the range of 100 Å-500 Å. The liner for an oxygen barrier is made of CVD silicon nitride and formed to a thickness of 50 Å-150 Å.

These and other features and aspects of the present invention will be readily apparent to those of ordinary skill in the art upon review of the detailed description that follows.

### BRIEF DESCRIPTION OF THE DRAWINGS

FIG. 1 through FIG. 4 illustrate cross-sectional views showing a peripheral part of a trench in order to expose conventional problems caused by a silicon nitride liner formed on an inner wall of the trench.

FIG. 5 through FIG. 7 illustrate cross-sectional views showing a shallow trench isolation technique adopting a conventional pull-back manner.

FIG. 8 illustrates a transmission electron micrograph (TEM) for exposing problems in a pull-back manner.

FIG. 9 through FIG. 15 illustrate flow diagrams showing the formation of a semiconductor device in accordance with an embodiment of the present invention.

FIG. 16 illustrates an enlarged view for clarifying a novel gate insulating layer at a corner part atop a silicon substrate.

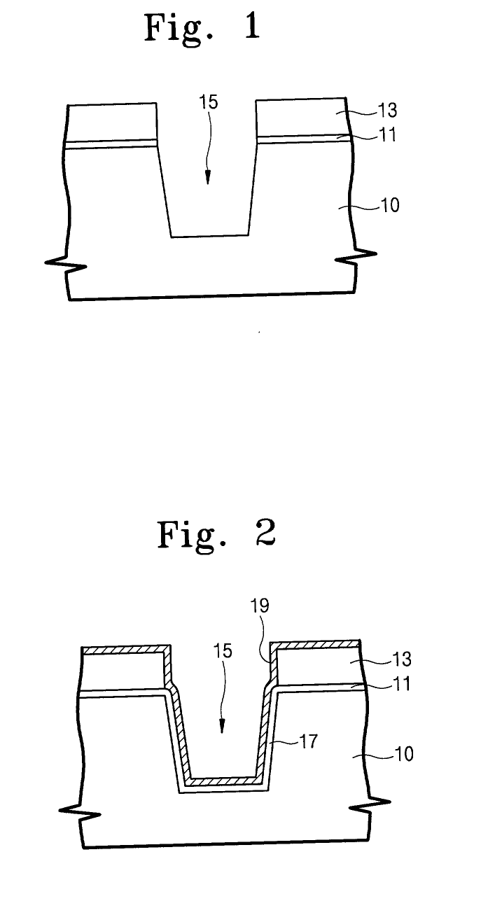

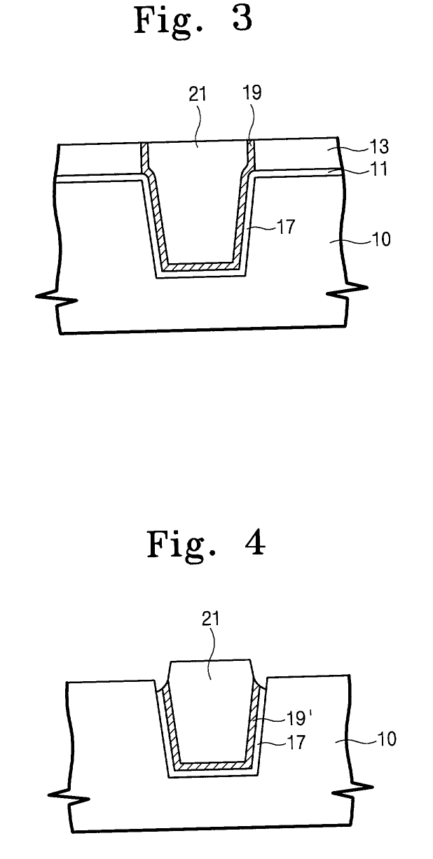

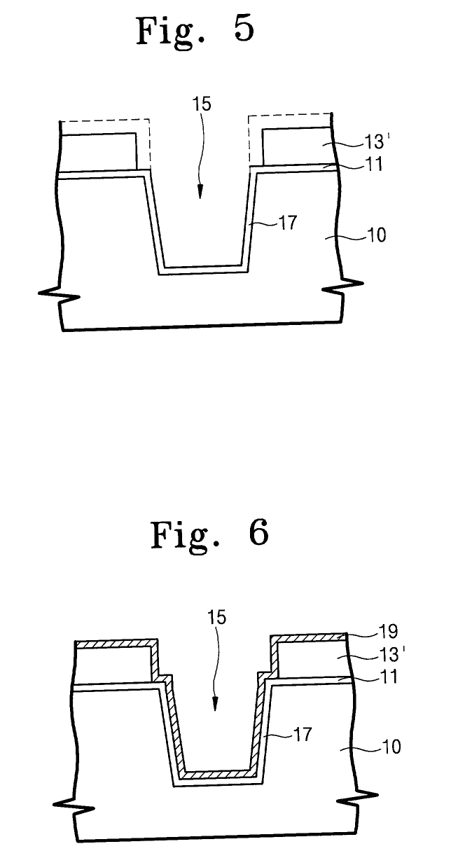

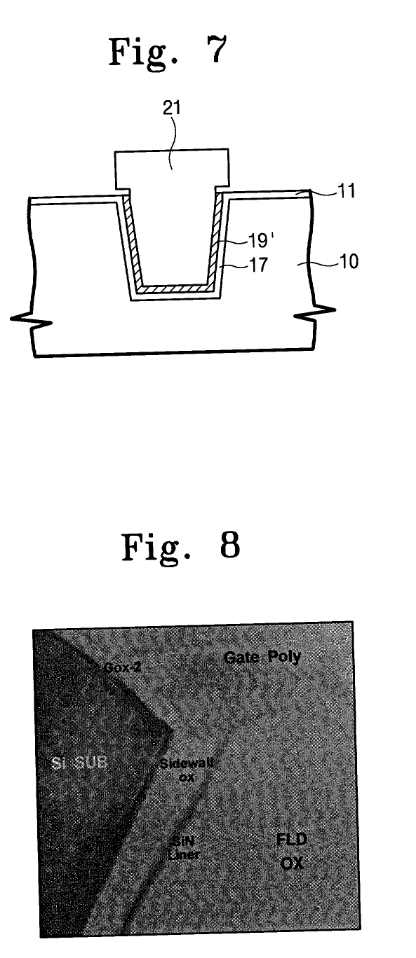

### DETAILED DESCRIPTION OF THE PREFERRED EMBODIMENT

Korean Patent Application No. 2000-39319, filed on Jul. 10, 2000, and entitled: “Shallow Trench Isolation Type Semiconductor Device and Method of the Same,” is incorporated by reference herein in its entirety.

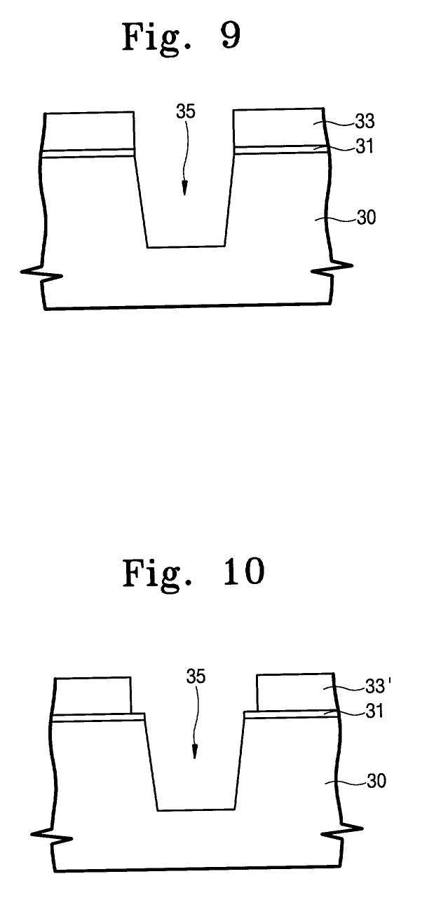

With reference to FIG. 9 through FIG. 14, there is shown the processing steps of forming a semiconductor device in accordance with an embodiment of the present invention. In FIG. 9, a pad oxide layer 31 is formed on a surface of a silicon substrate 30. An etch-stop layer 33 made of silicon nitride is stacked on the pad oxide layer 31, and is patterned. A sacrificial layer made of silicon oxide may be deposited on the etch-stop layer, and is conventionally patterned to act as a hard mask for etching the etch-stop layer 33. A pattern of the etch-stop layer 33 is formed, and the pad oxide layer in a trench area is removed. With removal of the photoresist pattern, the substrate 30 is etched to a predetermined depth to form a trench 35. If the photoresist pattern remains while etching the trench, it is removed by means of ashing and stripping processes.

Referring to FIG. 10, a pull-back manner is applied to substrate 30 in which trench 35 is formed. That is, an etch-stop layer covering an active region is isotropically etched so as to be decreased in thickness and width. Sidewalls of etch-stop layer pattern 33, formed at the extensions of the sidewalls of trench 35, are laterally reduced by 100Å-500 Å, thereby forming a shrunk pattern 33′. By means of this lateral etching, a liner, used as an oxygen barrier, will have a buffer portion to prevent a dent phenomenon during a wet etch for completely removing the etch-stop layer. The pad oxide layer 31 is scarcely removed, and the substrate 30 is angled at its top location that is close to the trench 35.

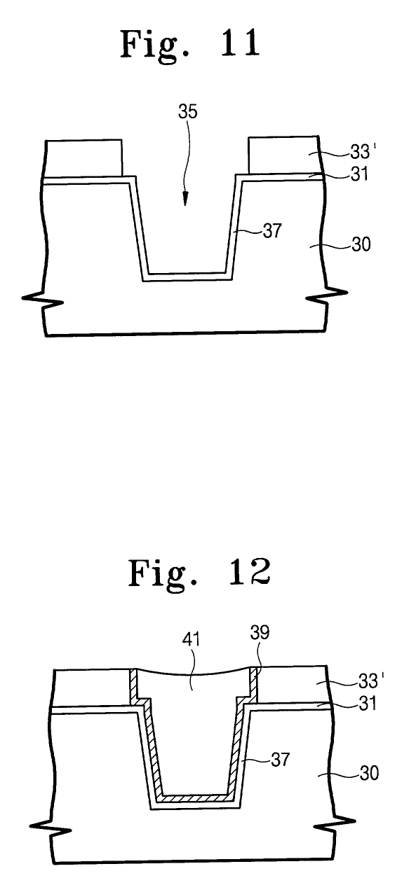

In FIG. 11, an inner wall of trench 35 is thermally oxidized at the substrate in which a shrunk pattern 33′ is formed. When silicon substrate 30 is damaged at an inner side of the trench in an etching step, this thermal oxidation cures the damage. In this case, the thermal oxide layer is preferably formed to a thickness of 20 Å-140 Å. Conventionally, determining a thickness of a trench sidewall oxide layer is dependent on the condition that the growth speed of a thermal oxide layer on an etch-damaged sidewall is approximately twice the value on an undamaged substrate's upper surface. The thickness of “20 Å-140 Å” is mainly based on a thickness of a thermal oxide layer that is grown on an etch-damaged sidewall.

Alternatively, after forming a thicker trench sidewall oxide layer, the thermal oxide layer is partially etched using an etchant such as HF and NH₄F of F-series to have a thickness of 20 Å-140 Å. In an alternate processing sequence, the thermal oxide layer is formed on the sidewall of the trench before the shrink pattern 33′ is formed.

Referring to FIG. 12, with an etch-stop layer shrunk 33′, a liner 39 for oxygen barrier is stacked on an entire surface of substrate 30. The liner 39 is made of silicon nitride using a chemical vapor deposition (CVD) technique and, preferably, has a thickness of 60 Å-70 Å. If the liner 39 is too thick, over-etch causes a dent phenomenon in spite of an etch-stop layer pull-back. Therefore, the thickness of the liner 39 is usually less than 150 Å. Since the liner 39 is conformally stacked on the entire surface of the substrate 30 and/or is made of the same material as the shrunk pattern 33′ of an etch-stop layer, formation of the liner 39 on the trench sidewall is significant. The liner 39 is formed on the pad oxide layer 31 of an active region, and laterally extends to the same length as the etch-stop layer that has been laterally shrunk.

A CVD silicon oxide layer is thickly formed to fill the trench 35. The CVD silicon oxide layer, which is formed on the shrunk pattern 33′ of the etch-stop layer, is planarized and removed to be a device isolation layer 41. In a CMP process, the liner 39 stacked on the shrunk pattern 33′ and a top portion of the shrunk pattern 33′ can also be partially removed. A width of the device isolation layer 41, which rises above the trench in the region between the shrunk patterns 33′, is greater than the width of the trench.

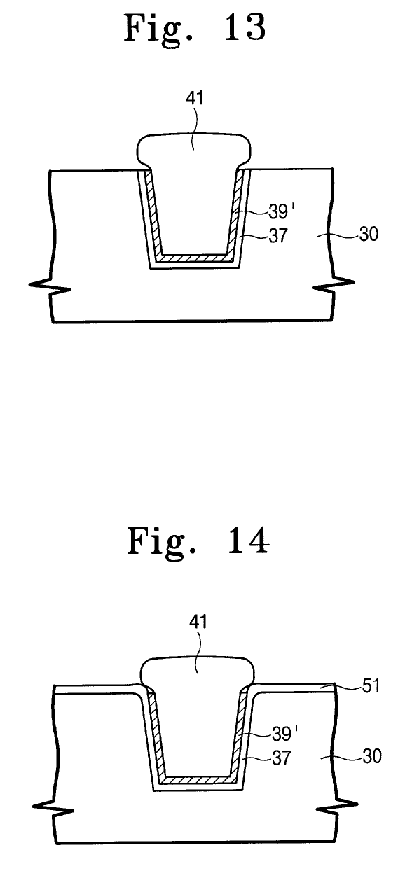

Referring to FIG. 13, a wet etch is carried out to remove the shrunk pattern 33′ of an etch-stop layer from the substrate 30. A phosphoric acid is mainly used in the wet-etch step. If the etch-stop layer is made of silicon oxynitride or silicon nitride employing a plasma manner, fluoride series can be mixed therewith. With removal of the shrunk pattern 33′, a sizable part of a sidewall liner 39 extending upwardly on the substrate 30 surface toward an active region is removed. The shrunk etch-stop layer 33′ and the pad oxide layer 31 thereunder are sequentially removed. At this time, the device isolation layer 41, which extends over the trench is also removed to a constant thickness.

Since the liner 39′ on the trench sidewall is not damaged, the dent phenomenon does not occur. Top of the liner 39′ is either written 150 Å below or at the same level as an adjacent surface layer of the silicon substrate. The liner 39′, creates a tension force on the trench sidewall oxide layer 37, which is close to lateral corners on top of the silicon substrate 30 and the trench.

Referring to FIG. 14, with a pad oxide layer removed, a buffer insulating layer 51 for ion implantation is formed on the active surface region of silicon substrate 30. The buffer insulating layer 51 is made of thermal oxide and hence is easily grown on the region where oxygen can be diffused quickly. Since it is shielded by a thermal oxide layer 37, a liner 39, and a CVD oxide layer 41, a corner on top of the substrate 30 adjacent to the trench is not expected to be oxidized properly. However, since a tension force of a sidewall liner 39′ acts on the corner to horizontally pull the substrate, oxygen easily penetrates between the silicon atoms of the corner region. Thus, the growth rate of the oxide layer is enhanced in the corner region. In other words, at the corner of the silicon substrate 30 adjacent to the trench, the tension of the liner 39′ compensates for the partial shield of the corner region by the lateral extension of the CVD oxide layer 41, and the substrate 30 is rapidly oxidized to form a buffer insulating layer that is thicker than the insulating layer at any other part of the active region.

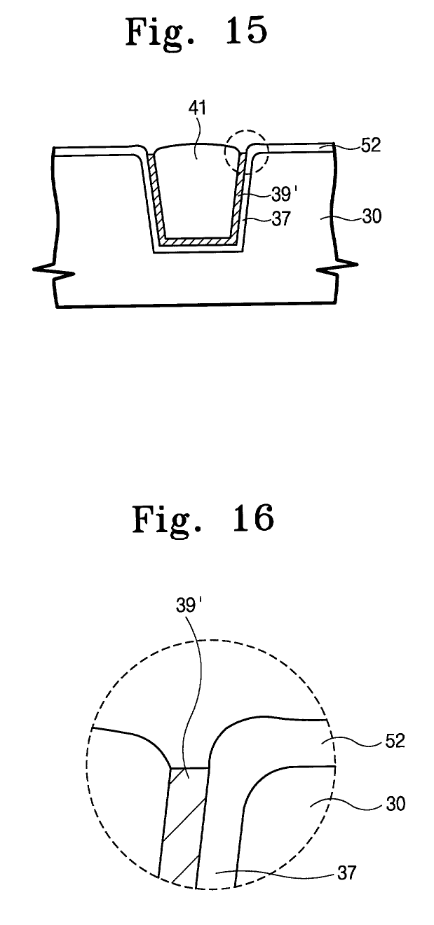

Referring to FIG. 15, the buffer oxide layer 51 is etched after implanting impurities over it. A gate insulating layer 52 is formed on silicon substrate 30 using a thermal oxidation technique. Similar to the formation of the buffer insulating layer 51 shown in FIG. 14, tension of a sidewall liner 39′ acts on a corner to horizontally pull substrate 30. Therefore, oxygen easily penetrates between silicon atoms in the corner regions of a crystal to enhance the growth rate of an oxide layer. This leads to formation of a thick gate insulating layer at a corner atop of the substrate 30 adjacent to the trench, and acquisition of a profile as illustrated in FIG. 16.

As explained so far, an etch-stop layer pull-back approach is carried out together with shallow trench isolation, for preventing the dent phenomenon. A thicker thermal oxide gate insulator is formed at the corner regions where the active regions of the substrate and the trench meet at the substrate surface due to an enhanced diffusion of the oxidizing species through the silicon crystal atoms in the corner regions, initiated by the tension forces of the trench liner layer in the corner regions. This enhances the stability of a gate insulator and the reliability of transistor operation.

A preferred embodiment of the present invention has been disclosed herein and, although specific terms are employed, they are used in a generic and descriptive sense only and not for purpose of limitation. Accordingly, it will be understood by those of ordinary skill in the art that various changes in form and details may be made without departing from the spirit and scope of the invention as set forth in the following claims.

What is claimed is:

1. A shallow trench isolation (STI) type semiconductor device employing a liner as an oxygen barrier, comprising:
a trench sidewall thermal oxide layer formed between the liner and a silicon substrate to a thickness of 20 Å-140 Å,
wherein a top of the liner is located at a position where a level difference from the top of the liner to an upper surface of the substrate is 150 Å or less.

2. The device of claim 1, wherein a thickness of the trench sidewall oxide layer is 50 Å-100 Å.

3. The device of claim 1, wherein a thickness of a gate insulating layer adjacent to the trench is identical to or greater than that of a gate insulating layer in the middle of an active region.

4. A method of forming a shallow trench isolation (STI) type semiconductor device, comprising:
etching a substrate where a pattern of an etch-stop layer covers an active region, forming a trench;
forming a thermal oxide layer on a sidewall of the trench;
isotropically etching the pattern and removing a lateral end of the pattern by a predetermined width, forming a shrunk pattern;
stacking a liner for an oxygen barrier on the thermal oxide layer of the substrate;
stacking a CVD silicon oxide layer on the substrate after the liner is formed, filling the trench;
removing and planarizing the CVD silicon oxide layer over the etch-stop layer;
removing the shrunk pattern; and
forming a gate oxide layer on the active region,
wherein a thickness of the thermal oxide layer on the sidewall of the trench is controlled to be 20 Å-140 Å during the stacking of the liner.

5. The method of claim 4, wherein the thickness of the thermal oxide layer is controlled to be 50 Å-100 Å.

6. The method of claim 4, wherein the etch-stop layer is made of silicon nitride.

7. The method of claim 4, wherein forming the thermal oxide layer occurs after forming the shrunk pattern.

8. The method of claim 4, wherein controlling the thermal oxide layer within a thickness range of 20 Å-140 Å is done by forming the thermal oxide layer of thickness greater than the required thickness range, and etching the thermal oxide layer to reach the thickness range by means of a fluorine (F)-contained etchant.

9. The method of claim 4, wherein the predetermined width in forming the shrunk pattern is 100 Å-500 Å.

10. The method of claim 4, wherein the liner comprises a CVD silicon nitride to a thickness of 50 Å-150 Å.

11. The method of claim 4, wherein removing the shrunk pattern is achieved by phosphoric acid wet etching.

12. The method of claim 6, wherein removing the shrunk pattern is achieved by wet etching in a mixture of fluorine contained etchant and phosphoric acid.

13. The method of claim 4, wherein the gate oxide layer is formed by a thermal oxidation technique.

14. The method of claim 13, wherein the thickness of the gate oxide layer adjacent to the trench is identical to or greater than that of the gate oxide layer in the middle of the active region.
